(19) United States
(12) Patent Application Publication
(10) Pub. No.: US 2012/0066902 A1
(43) Pub. Date: Mar. 22, 2012

(54) METHOD OF MANUFACTURING PRINTED CIRCUIT BOARD INCLUDING LANDLESS VIA

(75) Inventors: Han Kim, Gyunggi-do (KR); Je Gwang Yoo, Gyunggi-do (KR); Chang Sup Ryu, Gyunggi-do (KR); Chang Gun Oh, Gyunggi-do (KR)

(73) Assignee: SAMSUNG ELECTRO-MECHANICS CO., LTD., Suwon (KR)

(21) Appl. No.: 13/301,063

(22) Filed: Nov. 21, 2011

Related U.S. Application Data
(62) Division of application No. 12/219,079, filed on Jul. 15, 2008.

(30) Foreign Application Priority Data
May 27, 2008 (KR) 10-2008-0049277

(51) Int. Cl. H05K 3/10

(52) U.S. Cl. 29/852

(57) ABSTRACT

A method of manufacturing a printed circuit board, including: preparing a double-sided substrate which comprises an insulating layer, a first copper layer formed on one side of the insulating layer and a second copper layer formed on the other side of the insulating layer; forming a via-hole through the second copper layer and the insulating layer; forming a plating layer on an inner wall of the via-hole; and forming, on the double-sided substrate, a via, a first circuit layer including a circuit pattern that is formed on a surface of the via having a minimum diameter and has a line width smaller than the minimum diameter of the via, and a second circuit layer including a lower land.

### CROSS-REFERENCE TO RELATED APPLICATIONS

This application is a U.S. divisional application filed under 37 CFR 1.53(b) claiming priority benefit of U.S. Ser. No. 12/219,079 filed in the United States on Jul. 15, 2008, which claims earlier priority benefit to Korean Patent Application No. 10-2008-0049277 filed with the Korean Intellectual Property Office on May 27, 2008 the disclosures of which are incorporated herein by reference.

### BACKGROUND

1. Field

The present invention relates generally to a printed circuit board including a landless via and a method of manufacturing the printed circuit board, and, more particularly, to a printed circuit board including a landless via having no upper land, which includes a circuit pattern having a line width smaller than the minimum diameter of the via, and a method of manufacturing the printed circuit board.

2. Description of the Related Art

A printed circuit board, which is used for mounting and wiring electronic components, is typically manufactured in a manner such that a thin plate, such as a copper plate, is attached to one side of an insulating plate, such as a phenol resin plate, and an epoxy resin plate, the copper thin plate is etched along a wiring pattern of a circuit to form a desired circuit (i.e., the copper thin plate is removed by etching so as to leave a linear circuit), and holes are formed in the plate for mounting electronic components.

Printed circuit boards are classified into a single-sided PCB, which includes wiring on only one side thereof, a double-sided PCB, which includes wiring on both sides thereof, and a multilayered board (MLB), which includes wiring formed on a plurality of layers. In the past, since elements and devices as well as circuit patterns were relatively simple, single-sided PCBs were predominantly used. Recently, however, because the complexity of circuits and the need for compactness and miniaturization have increased, double-sided PCBs and MLBs are mainly used in most cases.

Each of most double-sided PCBs and MLBs includes a via for interconnection between layers. In this case, a land is essentially provided on a region at which the board is connected to a circuit of an upper layer through a via-hole, in order to assure stable electrical connection between the layers. The land is usually designed in consideration of an error in machining a via, an error in exposure equipment used for formation of an upper circuit, and deformation of process materials during the process. Since it is inevitable that deviations occur in equipment, materials and processes, the provision of lands is indispensable to the manufacture of printed circuit boards in order to improve productivity and process yield. Meanwhile, with the development of the electronics industry, high-density semiconductors are developed, and compactness and slimness of electronic components are promoted, with the result that printed circuit boards, on which the electronic components are mounted, are also required to be compact and slim and have high density. To this end, intensive efforts are being ceaselessly put into the realization of fine wiring of printed circuit boards and fine spacing between vias, but there is a limit to the realization of high-density printed circuit boards due to the presence of lands. Further, in order to enhance the interlayer aligning ability of a high-density printed circuit board, the ability of laser equipment to perform alignment in order to form a via is enhanced, or novel exposure equipment having a high aligning ability, which is adapted to form a fine circuit, is being developed. However, there are limitations in that the development of such equipment requires a prolonged period of time and the lands cannot be completely obviated.

FIG. 1 is a cross-sectional view of a printed circuit board, which is manufactured in a conventional way so as to include a double-sided substrate 1, an insulating layer 2 formed on the double-sided substrate 1, a via 7 formed in the insulating layer 2, and a circuit layer formed on the insulating layer. Referring to FIG. 1, the via 7, which is formed in the printed circuit board, includes an upper land 4 which is wider than the diameter of the via 7. The upper land 4 is sized so as to allow stable copper electroplating after the formation of the via-hole, in consideration of deviation of a laser for forming a via-hole and deviation of exposure. Typically, the upper land 4 is designed to have an area equal to or greater than seven times the area of the upper surface of the via 7, and the upper land 4 occupies a substantial portion of the area of the printed circuit board, thus impeding the formation of a high-density circuit. In particular, in the case in which a circuit layer, on which an upper land is formed, is disposed on a printed circuit board which includes semiconductor chips mounted thereon and thus requires maximum density circuits, the manufacture of small-sized printed circuit boards suffers from a serious problem.

### SUMMARY

Accordingly, the present invention has been made keeping in mind the above problems occurring in the prior art, and the present invention provides a printed circuit board which includes a landless via, in which a circuit pattern is formed on the end of the via having the minimum diameter and has a line width smaller than the minimum diameter of the via, and a method of manufacturing the printed circuit board.

In one aspect, the present invention provides a printed circuit board, including: an insulating layer; a first circuit layer including a circuit pattern, formed on one side of the insulating layer; a second circuit layer including a lower land, formed on the other side of the insulating layer; and a via for electrical connection between the circuit pattern and the lower land; wherein the via is configured such that a diameter of the via is decreased toward the circuit pattern from the lower land and the circuit pattern has a line width smaller than a minimum diameter of the via.

The circuit pattern may extend across an end surface of the via.

In another aspect, the present invention provides a method of manufacturing a printed circuit board, comprising: preparing a double-sided substrate which comprises an insulating layer, a first copper layer formed on one side of the insulating layer and a second copper layer formed on the other side of the insulating layer; forming a via-hole through the second copper layer and the insulating layer; forming a plating layer on an inner wall of the via-hole; and forming, on the double-sided substrate, a via, a first circuit layer including a circuit pattern that is formed on a surface of the via having a minimum diameter and has a line width smaller than the minimum diameter of the via, and a second circuit layer including a lower land.

The first copper layer may include a lower copper layer formed on the insulating layer and an upper copper layer formed on the lower copper layer, and the lower and upper copper layers may be attached to each other using a releasing agent.

The forming the via, the first circuit layer and the second circuit layer may be conducted through an additive process.

The forming the via, the first circuit layer and the second circuit layer may includes: removing the upper copper layer; forming a first resist layer on the lower copper layer and forming a second resist layer on the second copper layer; patterning the first and second resist layers such that the first resist layer has an opening for forming the first circuit layer including the circuit pattern having a line width smaller than the minimum diameter of the via and the second resist layer has an opening for forming the second circuit layer including the lower land; and subjecting the openings to metal plating and removing the remaining first and second resist layers.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a conventional printed circuit board including a via having an upper land;

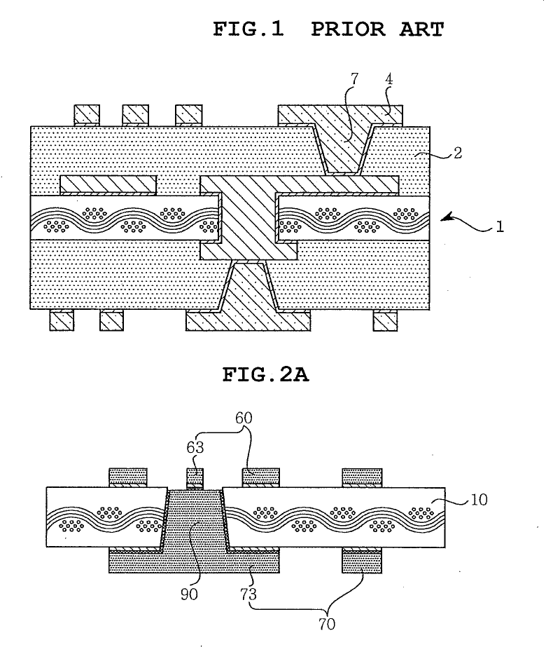

FIG. 2A is a cross-sectional view of a printed circuit board including a landless via-hole, according to an embodiment of the present invention;

FIG. 2B is a plan view of the printed circuit board shown in FIG. 2A, as viewed from above; and

FIGS. 3 to 10 are cross-sectional views showing a process of manufacturing the printed circuit board including a landless via, according to the embodiment of the present invention.

### DESCRIPTION OF EMBODIMENTS

Hereinafter, a printed circuit board including a landless via according to the present invention will be described in greater detail with reference to the accompanying drawings. Throughout the accompanying drawings, the same reference numerals are used to designate the same or similar components, and redundant descriptions thereof are omitted. In the following description, the terms “first”, “second” and the like are used to differentiate a certain component from other components, but the configuration of such components should not be construed to be limited by the terms.

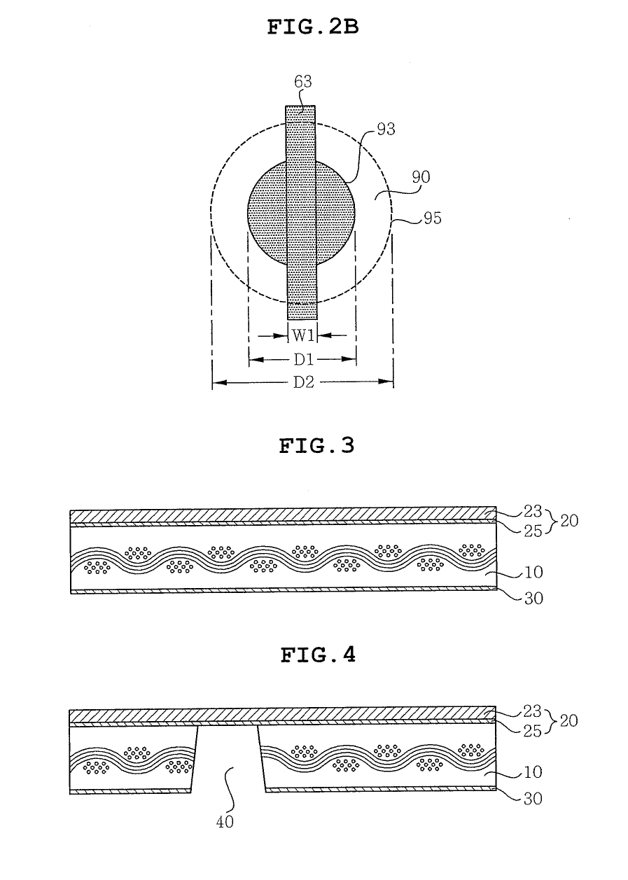

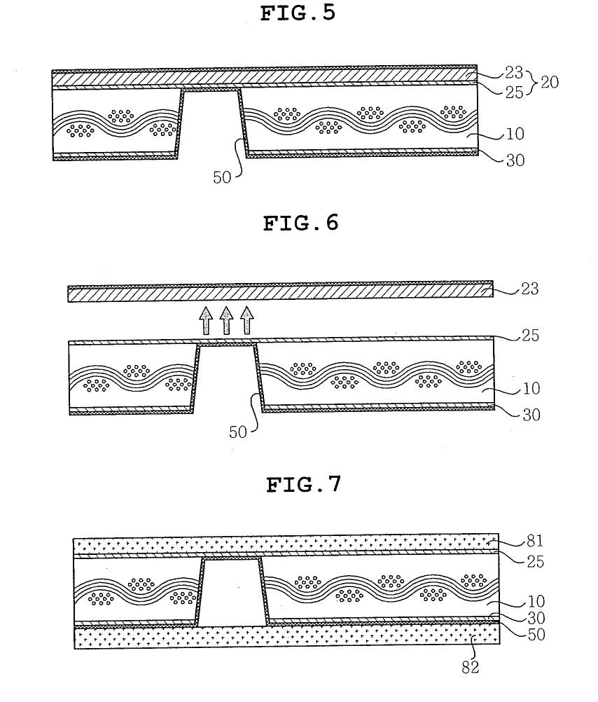

FIG. 2A is a cross-sectional view of a printed circuit board including a landless via, according to an embodiment of the present invention, and FIG. 2B is a plan view of the printed circuit board shown in FIG. 2A, which shows the region of the printed circuit board in which the via is formed. As shown in FIGS. 2A and 2B, the present invention is configured such that a circuit pattern 63, which is provided on the upper surface 93 of the via 90 having the minimum diameter along the length thereof, has a line width smaller than the minimum diameter of the via 90.

The via 90 is adapted to electrically connect the circuit pattern 63 to a lower land 73. In this embodiment, the via 90 is configured such that the diameter thereof is decreased toward the circuit pattern 63 from the lower land 73. In one embodiment, the via 90 may have a conical form in which the diameter thereof is decreased at a constant rate. When a CO2 laser drill or a YAG laser drill, which is usually used in the formation of via-holes, is used to form a via-hole 40, the via 90 may have a frusto-conical structure. In this embodiment, the via 90 is comprised of, for example, copper.

The circuit pattern 63 is a conductive line which is in contact with the upper surface 93 of the via 90 in a surface-to-surface manner. In this embodiment, the circuit pattern 63 is formed on the upper surface 93 of the via 90 having the minimum diameter, and has a line width W1 smaller than the minimum diameter D1 of the via 90.

The via 90, which is formed using the laser drill, has the frusto-conical structure having a diameter which is decreased at a constant rate, as described above. In this case, a first circuit layer 60, which is formed on the upper surface 93 of the via 90 having the minimum diameter D1, may be configured to have a higher density than a second circuit layer 70, which is connected to the lower surface 95 of the via 90 having the maximum diameter D2. In other words, the smaller the surface of the via, the higher the density of the circuit pattern. In particular, when the circuit pattern 63 is used as a bonding pad on a mounting surface of a semiconductor chip (not shown) which requires a high density, the effect resulting from the use of the circuit pattern is considerably high.

Further, since the circuit pattern 63 according to this embodiment is formed on the upper surface 93 of the via 90 having the minimum diameter and has a line width W1 smaller than the minimum diameter D1 of the via 90, the circuit pattern 63 may realize a circuit having a higher density than the first circuit layer 70 formed under the via 90.

Referring to FIG. 2B, the circuit pattern 63 according to this embodiment is configured to extend across the upper surface 93 of the via 63 while being in contact with the upper surface 93 in a surface-to-surface manner. Accordingly, the electrical connection of the circuit pattern is better than a conventional landless circuit pattern which is connected to a plating layer on the inner wall of a via.

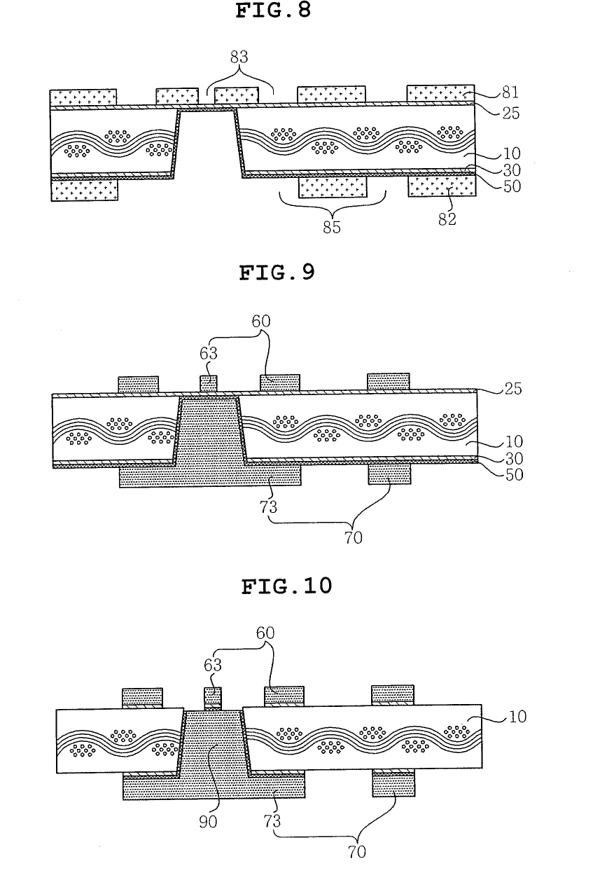

The process of manufacturing the printed circuit board including a landless via, according to an embodiment of the present invention, will now be described. FIGS. 3 to 10 are flow process views sequentially showing the process of manufacturing the printed circuit board including a landless via.

As shown in FIG. 3, an insulating layer 10, which includes a first copper layer 20 formed on the upper surface thereof and a second copper layer 30 formed on the lower surface thereof, is prepared. The first copper layer 20 is comprised of two layers, i.e., a first lower copper layer 25 and a first upper copper layer 23 formed on the first lower copper layer 25. In this embodiment, first the lower copper layer 25 may have a thickness of about 3 μm, the first upper copper layer 23 may have a thickness of about 18 μm, and the second copper layer 30 may have a thickness of about 3 μm.

Thereafter, as shown in FIG. 4, a via-hole 40, which passes through the second copper layer 30 and the insulating layer 10, is formed. In this embodiment, the via-hole 40 is formed, starting from the second copper layer 30, using a laser drill employing a CO2 or YAG laser. Prior to machining using the laser drill, a window-formation operation of removing the portion of the second copper layer 30 corresponding to the via-hole 40 may be optionally conducted in advance. When the via-hole 40 is formed using a laser drill, as in the embodiment shown in the drawing, on account of the intrinsic properties of the laser, the via-hole 40 tends to decrease in diameter at a constant rate in a direction away from the laser-irradiated surface, i.e., in a direction toward the first copper layer 20 from the second copper layer 30.

Subsequently, as shown in FIG. 5, an electroless plating operation is conducted to form an electroless plating layer 50 on the second copper layer 30 and the inner surface of the via-hole 40. At this point, the electroless plating operation is a pretreatment operation for providing a conductive film required to form the via 90 using electroless copper plating.

As shown in FIG. 6, the upper copper layer 23 of the first copper layer 20 is removed. In this regard, since the upper copper layer 23 and the lower copper layer 25 are attached to each other using, for example, a releasing agent, the two copper layers 23 and 25 may be easily detached from each other. In place of the releasing agent, any other known materials may also be used, as long as the materials enable the upper copper layer 23 and the lower copper layer 25 to be detached from each other.

As shown in FIG. 7, a first resist layer 81 is formed on the lower copper layer 25, and a second resist layer 82 is formed on the second copper layer 30. In this embodiment, each of the first resist layer 81 and the second resist layer 82 may be embodied as a photosensitive resist film.

As shown in FIG. 8, the first resist layer 81 and the second resist layer 82 are patterned. More specifically, the first and second resist layers 81 and 82 are patterned in a manner such that the first and second resist layers 81 and 82 are subjected to light exposure and development processes so that the first resist layer 81 has openings 83 for forming a first circuit layer 60 including a circuit pattern 63 and the second resist layer 82 has openings 85 for forming a second circuit layer 70 including a lower land 73. At this point, the openings 83 for forming the circuit pattern 63, which are formed on the via 90, are narrower than the minimum diameter D1 of the via 90.

As shown in FIG. 9, the openings 83 and 85 of the first and second resist layers 81 and 82 are subjected to electroplating, and then the remaining first and second resist layers 81 and 82 are removed. At this time, in this embodiment, a copper fill plating process is conducted to form the via 90.

Subsequently, as shown in FIG. 10, flesh etching is conducted so as to remove the lower copper layer 25, the electroless plating layer 50 and the second copper layer 30, thus forming the first and second circuit layers 60 and 70. As a result of the above-described process, a printed circuit board is manufactured, which includes the circuit pattern 63, which is formed on the surface of the via 90 having the minimum diameter and has a line width smaller than the minimum diameter of the via 90.

Although the present embodiment has been described and illustrated as being conducted in a manner such that the first circuit layer 60 and the second circuit layer 70 are simultaneously formed through an additive process (including a semi-additive process and a modified semi-additive process), another process, in which the second circuit layer 70 including the lower land 73 and the via 90 are first formed and then the first circuit layer 60 including the circuit pattern 63 is formed, may also be conducted, and this process should also be understood to fall within the scope of the present invention.

As described above, the printed circuit board including a landless via according to the present invention has an advantage in that there is no upper land on the end surface of a via having the minimum diameter, so that a circuit pattern connected to the via may be finely formed, thus enabling the circuit pattern and the outermost circuit layer of the printed circuit board to be realized at high density.

Further, the printed circuit board including a landless via according to the present invention has another advantage in that the printed circuit board can be easily manufactured using upper and lower copper layers, which are removably attached to each other through a releasing agent.

Although the preferred embodiment of the present invention has been disclosed for illustrative purposes, those skilled in the art will appreciate that various modifications, additions and substitutions are possible, without departing from the scope and spirit of the invention as disclosed in the accompanying claims. Accordingly, the modifications, additions and substitutions should also be understood to fall within the scope of the present invention.

What is claimed is:

1. A method of manufacturing a printed circuit board, comprising:
preparing a double-sided substrate which comprises an insulating layer, a first copper layer formed on one side of the insulating layer and a second copper layer formed on the other side of the insulating layer;
forming a via-hole through the second copper layer and the insulating layer;
forming a plating layer on an inner wall of the via-hole; and
forming, on the double-sided substrate, a via, a first circuit layer including a circuit pattern that is formed on a surface of the via having a minimum diameter and has a line width smaller than the minimum diameter of the via, and a second circuit layer including a lower land.

2. The method according to claim 1, wherein the first copper layer includes a lower copper layer formed on the insulating layer and an upper copper layer formed on the lower copper layer, and the lower and upper copper layers are attached to each other using a releasing agent.

3. The method according to claim 1, wherein the forming the via, the first circuit layer and the second circuit layer is conducted through an additive process.

4. The method according to claim 2, wherein the forming the via, the first circuit layer and the second circuit layer comprises:
removing the upper copper layer;
forming a first resist layer on the lower copper layer and forming a second resist layer on the second copper layer;
patterning the first and second resist layers such that the first resist layer has an opening for forming the first circuit layer including the circuit pattern having a line width smaller than the minimum diameter of the via and the second resist layer has an opening for forming the second circuit layer including the lower land; and
subjecting the openings to metal plating and removing the remaining first and second resist layers
